(19) United States
(12) Patent Application Publication
(10) Pub. No.: US 2025/0056886 A1
(43) Pub. Date: Feb. 13, 2025

(54) ARRAY SUBSTRATE AND DISPLAY DEVICE

(71) Applicant: Japan Display Inc., Tokyo (JP)

(72) Inventor: Hirotaka HAYASHI, Tokyo (JP)

(73) Assignee: Japan Display Inc., Tokyo (JP)

(21) Appl. No.: 18/792,696

(22) Filed: Aug. 2, 2024

(30) Foreign Application Priority Data
Aug. 10, 2023 (JP) 2023-131152

(51) Int. Cl. H01L 27/12; G02F 1/1362; G02F 1/1368

(52) U.S. Cl. CPC H01L 27/124; G02F 1/136286; G02F 1/1368

(57) ABSTRACT

According to one embodiment, an array substrate includes a transparent substrate, a linear source electrode disposed on the transparent substrate, a linear drain electrode disposed on a same layer as that of the source electrode, at least two semiconductor members connected in parallel between the source electrode and the drain electrode, and a gate electrode overlapping the source electrode, the drain electrode and the at least two semiconductor members, and the gate electrode has a notch formed in a region between the at least two semiconductor members.

### CROSS-REFERENCE TO RELATED APPLICATIONS

This application is based upon and claims the benefit of priority from Japanese Patent Application No. 2023-131152, filed Aug. 10, 2023, the entire contents of which are incorporated herein by reference.

### FIELD

Embodiments described herein relate generally to an array substrate and a display device.

### BACKGROUND

In recent years, various display devices using polymer dispersed liquid crystals that can switch between a scattering state, in which incident light is scattered, and a transparent state, in which incident light is transmitted, have been proposed. Such display devices have an array substrate on which thin-film transistors are formed. In some array substrates, a plurality of small thin-film transistors may be arranged in close proximity. With this configuration, the heat generated when current flows through the thin-film transistors can be suppressed as compared to the case where one large thin-film transistor is arranged in the same area.

On the other hand, when multiple thin-film transistors are arranged in close proximity, gaps are created between these thin-film transistors, and the load capacitance increases in these gaps. Such an increase in load capacitance adversely may affect the display quality and life (service life) of the display device and reduce the reliability of the display device.

### BRIEF DESCRIPTION OF THE DRAWINGS

FIG. 1 is a plan view showing an example of a display device according to an embodiment.

FIG. 2 is a diagram illustrating the configuration of pixels of a display panel of the embodiment.

FIG. 3 is a plan view showing various elements including switching elements disposed near a region where scanning lines and signal lines intersect.

FIG. 4 is a plan view showing various elements including switching elements disposed near a region where scanning lines and signal lines intersect.

FIG. 5 is a plan view showing in detail elements that constitute a switching element according to the first embodiment.

FIG. 6 is a cross-sectional view

schematically showing the display panel taken along the line A-B in FIG. 5.

FIG. 7 is a cross-sectional view schematically showing the display panel taken along the line C-D in FIG. 5.

FIG. 8 is a plan view showing in detail elements that constitute a switching element according to the second embodiment.

FIG. 9 is a cross-sectional view schematically showing the display panel taken along the line E-F in FIG. 8.

FIG. 10 is a plan view showing in detail elements that constitute a switching element according to the third embodiment.

FIG. 11 is a cross-sectional view schematically showing the display panel taken along the line G-H in FIG. 10.

### DETAILED DESCRIPTION

In general, according to one embodiment, an array substrate comprises a transparent substrate, a linear source electrode disposed on the transparent substrate, a linear drain electrode disposed on a same layer as that of the source electrode, at least two semiconductor members connected in parallel between the source electrode and the drain electrode, and a gate electrode overlapping the source electrode, the drain electrode and the at least two semiconductor members, and the gate electrode has a notch formed in a region between the at least two semiconductor members.

According to another embodiment, a display device comprises a transparent substrate, a linear source electrode disposed on the transparent substrate, a linear drain electrode disposed on a same layer as that of the source electrode, at least two semiconductor members connected in parallel between the source electrode and the drain electrode, and a gate electrode overlapping the source electrode, the drain electrode and the at least two semiconductor members, and the gate electrode has a notch formed in a region between the at least two semiconductor members.

Embodiments will be described hereinafter with reference to the accompanying drawings.

Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

In the following embodiments, a liquid crystal display device will be described as an example of the display devices. The main configuration disclosed in these embodiment is applicable to, not only electrophoretic displays and displays with self-luminescent light-emitting elements such as organic electroluminescent (EL) elements, micro-LEDs, and mini-LEDs, but also to various electronic devices such as capacitive sensors and optical sensors.

### First Embodiment

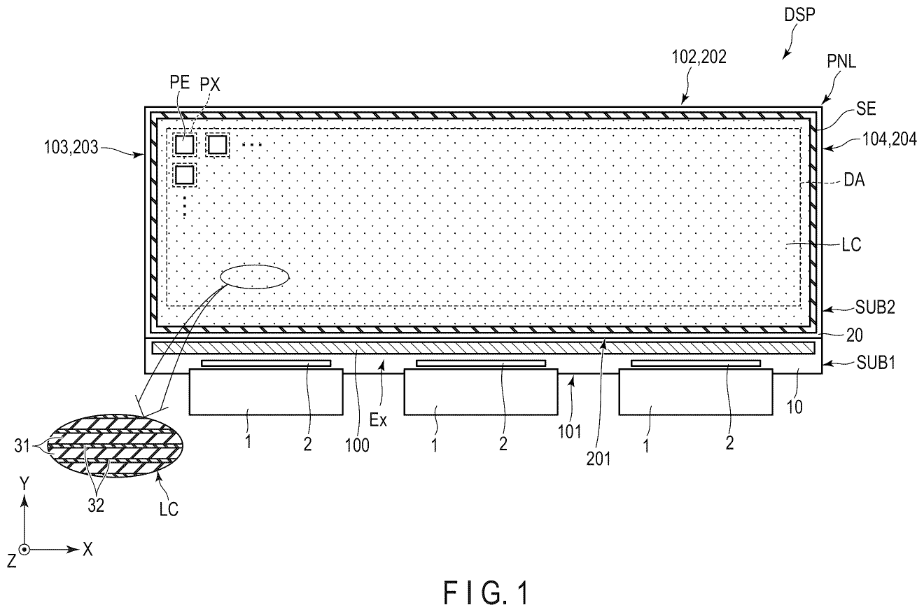

FIG. 1 is a plan view showing an example of a display device DSP of an embodiment. For example, a first direction X, a second direction Y and a third direction Z are orthogonal to each other, but may intersect at an angle other than 90 degrees. The first direction X and the second direction Y correspond to directions parallel to the main surface of the substrate that constitutes the display device DSP, and the third direction Z corresponds to the thickness direction of the display device DSP. In this embodiment, viewing an X-Y plane defined by the first direction X and the second direction Y is referred to as plan view.

The display device DSP comprises a display panel PNL, a wiring substrate 1, an IC chip 2, and a light emitting module 100.

The display panel PNL is a so-called transparent display and comprises a first substrate SUB1 (array substrate), a second substrate SUB2 (counter-substrate), a liquid crystal layer LC containing polymer dispersed liquid crystals, and a seal SE. The first substrate SUB1 and the second substrate SUB2 are formed as flat plates along an X-Y plane. The first substrate SUB1 and the second substrate SUB2 are arranged to overlap each other in plan view. The region where the first substrate SUB1 and the second substrate SUB2 overlap each other includes a display area DA which displays images.

The display area DA comprises a plurality of pixels PX arranged in a matrix along the first direction X and the second direction Y. These pixels PX are indicated by dotted lines in the figure. Each of the pixels PX comprises a pixel electrode PE indicated by a solid square in the figure.

The first substrate SUB1 comprises a first transparent substrate 10 and the second substrate SUB2 comprises a second transparent substrate 20. The first transparent substrate 10 includes side surfaces 101 and 102 along the first direction X and side surfaces 103 and 104 along the second direction Y. The second transparent substrate 20 includes side surfaces 201 and 202 along the first direction X and side surfaces 203 and 204 along the second direction Y.

In the example shown in FIG. 1, the side surfaces 102 and 202, the side surfaces 103 and 203, and the side surfaces 104 and 204 overlap each other in plan view, respectively, but they may not necessarily be set to overlap. The side surface 201 is not located to overlap the side surface 101 and is located between the side surface 101 and the display area DA. The first substrate SUB1 includes an extended portion Ex located between the side surface 101 and the side surface 201. In other words, the extended portion Ex corresponds to the portion of the first substrate SUB1 that extends in the second direction Y from the portion that overlaps the second substrate SUB2, and therefore it does no overlap the second substrate SUB2.

Further, in the example shown in FIG. 1, the display panel PNL is formed in a rectangular shape elongated along the first direction X. That is, the side surfaces 101 and 102, and the side surfaces 201 and 202 are side surfaces along the long edges of the display panel PNL, respectively and the side surfaces 103 and 104, and the side surfaces 203 and 204 are side surfaces along the short edges of the display panel PNL, respectively. The display panel PNL may be formed into a rectangular shape elongated along the second direction Y, into a square shape, into some other polygonal shape, or into other shapes such as circular or oval.

The wiring substrate 1 and the IC chip 2 are mounted on the extended portion Ex. The wiring substrate 1 is, for example, a bendable flexible printed circuit board. The IC chip 2 contains, for example, a display driver built-therein, that outputs signals necessary for image display. Note that the IC chip 2 may be mounted on the circuit board 1. In the example shown in FIG. 1, a plurality of wiring boards 1 are mounted to the display panel PNL so as to be aligned along the first direction X, but a single wiring board 1 may be mounted to extend along the first direction X. Further, although a plurality of IC chips 2 are mounted to the display panel PNL so as to be aligned in the first direction X, a single IC chip 2 may be mounted to extend along the first direction X.

The light emitting module 100 is disposed to overlap the extended portion Ex in plan view and to be along the side surface 201 of the second transparent substrate 20.

The seal SE adheres the first substrate SUB1 and the second substrate SUB2 together. The seal SE is formed into a rectangular frame shape and surrounds the liquid crystal layer LC between the first substrate SUB1 and the second substrate SUB2.

The liquid crystal layer LC is held between the first substrate SUB1 and the second substrate SUB2. The liquid crystal layer LC with such a configuration is arranged over the area surrounded by the seal SE (including the display area DA) in plan view.

As enlargedly and schematically shown in FIG. 1, the liquid crystal layer LC includes polymers 31 and liquid crystal molecules 32. In one example, the polymers 31 are of a liquid crystalline type. The polymers 31 are each formed into a stripe shape extending along the first direction X and aligned along the second direction Y. The liquid crystal molecules 32 are dispersed in the gaps of the polymers 31 and are aligned so that their long axes are set along the first direction X. Each of the polymers 31 and the liquid crystal molecules 32 has an optical anisotropy or refractive index anisotropy. The responsivity of the polymers 31 to an electric field is lower than the responsivity of the liquid crystal molecules 32 to the electric field.

In one example, the alignment direction of the polymers 31 does not substantially change regardless of the presence or absence of an electric field. On the other hand, the alignment direction of the liquid crystal molecules 32 changes according to an electric field when a voltage higher than or equal to a threshold value is being applied to the liquid crystal layer LC. When no voltage is being applied to the liquid crystal layer LC (initial alignment state), the respective optical axes of the polymers 31 and liquid crystal molecules 32 are substantially parallel to each other, and light incident on the liquid crystal layer LC is substantially completely transmitted therethrough (transparent state). When the voltage is being applied to the liquid crystal layer LC, the alignment direction of the liquid crystal molecules 32 changes and the respective optical axes of the polymers 31 and liquid crystal molecules 32 cross each other. Therefore, light incident on the liquid crystal layer LC is scattered within the liquid crystal layer LC (scattered state).

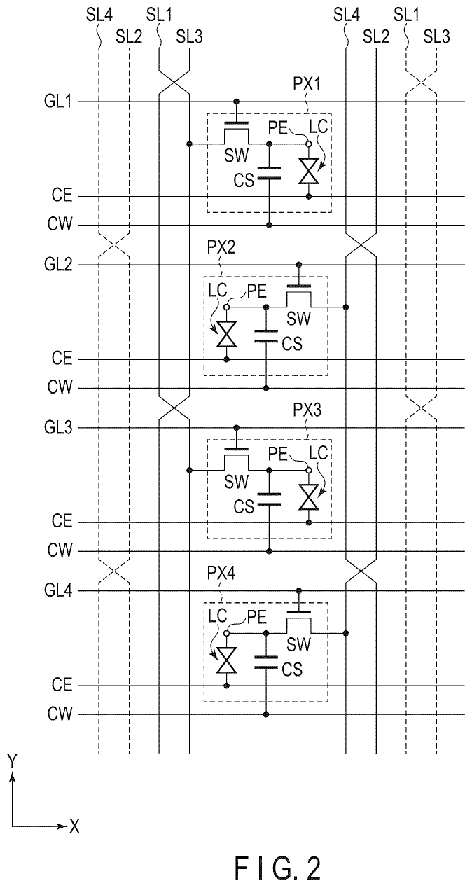

FIG. 2 is a diagram illustrating the configuration of the pixels PX of the display panel PNL of the embodiment. As shown in FIG. 2, this embodiment describes a configuration in which scanning signals can be supplied to four scanning lines GL1 to GL4, respectively, at the same time and video signals can be written at the same time to four pixels PX1 to PX4 aligned along the second direction Y using four signal lines SL1 to SL4, respectively.

According to this configuration, one horizontal period can be prolonged as compared to that of the configuration in which scanning signals are sequentially supplied per line. More specifically, the time required for scanning all pixels can be reduced to ¼ of the time required in the configuration in which scanning signals are sequentially supplied per line. Therefore, with this configuration, it is possible to secure sufficient time for writing video signals in a high-speed drive panel such as a transparent display or in a large high-definition panel.

Note here that a configuration in which scanning signals are simultaneously supplied to the four scanning lines GL1 to GL4, respectively, and video signals are simultaneously written to the four pixels PX1 to PX4 aligned along the second direction Y using the four signal lines SL1 to SL4, respectively (that is, a configuration in which scanning signals are supplied every four lines and video signals are written every four lines) is described. But, the configuration of the display panel PNL is not limited to this, and for example, it may be configured to supply scanning signals for each line and write video signals for each line.

As described above, in FIG. 2, four pixels PX1 to PX4 are aligned along the second direction Y. Each of the four pixels PX1 to PX4 is electrically connected to each of the four scanning lines GL1-GL4. Each of the four pixels PX1 to PX4 is electrically connected to each of the four signal lines SL1-SL4. Furthermore, each of the four pixels PX1 to PX4 is electrically connected to each of capacitive line CW. In the following description, when the four pixels PX1 to PX4 are not specifically distinguished from each other, they are simply described as pixels PX. Similarly, when the four scanning lines GL1 to GL4 are not particularly distinguished, they will be described simply as scanning lines GL, and when the four signal lines SL1 to SL4 are not particularly distinguished, they will be described simply as signal lines SL.

The pixels PX each comprises a switching element SW. The switching element SW is constituted by a thin-film transistor (TFT), for example, and is electrically connected to the respective scanning line GL and the respective signal line SL. More specifically, the gate electrode of the switching element SW is connected to the scanning line GL, the source electrode of the switching element SW is connected to the signal line SL, and the drain electrode of the switching element SW is connected to the pixel electrode PE.

The common electrode CE and the capacitive lines CW are arranged over the display area DA and its peripheral areas. To the common electrode CE, a predetermined voltage is applied. To the capacitive lines CW, for example, a voltage of the same potential as that of the common electrode CE is applied.

The pixel electrode PE is disposed to oppose the common electrode CE along the third direction Z. In the display area DA, the liquid crystal layer LC (in particular, the liquid crystal molecules 32) is driven by the electric field generated between the pixel electrode PE and the common electrode CE. A capacitance CS is formed, for example, between the respective capacitive line CW and the pixel electrode PE.

The switching element SW has a function of controlling the writing time of the video signal supplied from the signal line SL to the pixel PX by switching between the on state and off state. By setting the switching element SW to the on state, the potential corresponding to the video signal supplied from the signal line SL can be written to the capacitance CS. Further, by setting the switching element SW to the off state, the potential held in the capacitance CS can be retained.

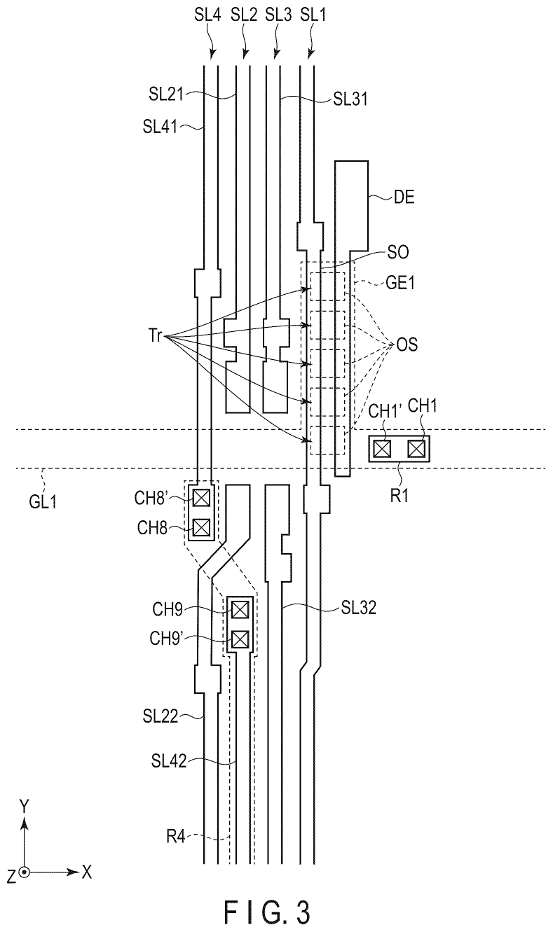

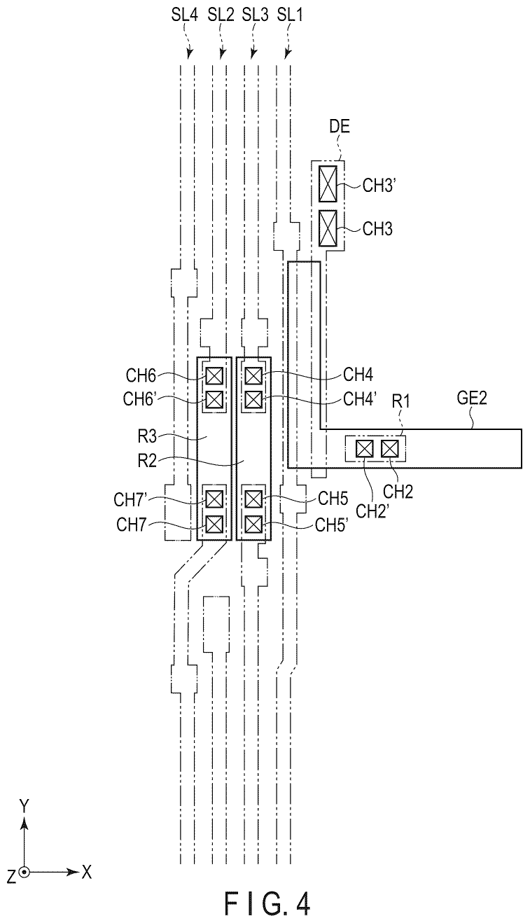

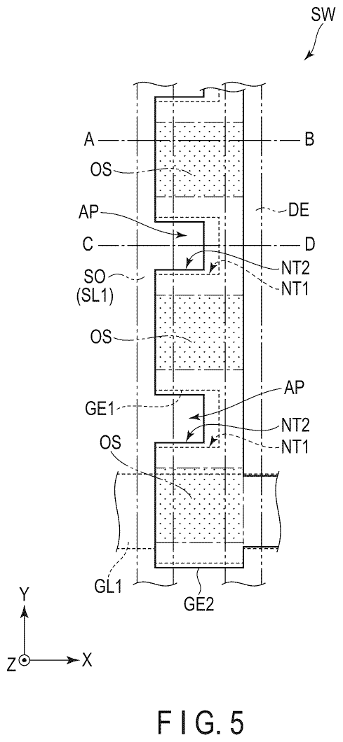

FIGS. 3 and 4 are plan views each showing various elements including the switching element SW which is located near the region where scanning lines GL and signal lines SL intersect each other. Note that in FIGS. 3 and 4, the shapes of the elements which constitute the switching element SW (in particular, the shapes of the first gate electrode GE1 and the second gate electrode GE2) are shown in a simplified manner. The detailed shapes of these elements will be described late with reference to FIG. 5.

The switching element SW comprises a semiconductor member OS, a first gate electrode GE1 integrated with the scanning line GL1, a source electrode SO integrated with the signal line SL1, a drain electrode DE, and a second gate electrode GE2.

The semiconductor member OS is an oxide semiconductor. The semiconductor member OS may be a silicon-based semiconductor such as polycrystalline silicon or amorphous silicon. In the example shown in FIG. 3, five semiconductor members OS are arranged to overlap the first gate electrode GE1 and aligned along the second direction Y at intervals. The five semiconductor members OS each constitute a transistor Tr. The second gate electrode GE2 is disposed to overlap the first gate electrode GE1 and the semiconductor members OS. The second gate electrode GE2 is disposed to further overlap the scanning line GL1, and between the scanning line GL1 and the second gate electrode GE2, a relay electrode R1 is interposed.

A contact holes CH1 is formed in the insulating film interposed between the scanning line GL1 and the relay electrode R1. The relay electrode R1 is in contact with the scanning line GL1 in the contact hole CH1. A contact hole CH2 is formed in the insulating film interposed between the relay electrode R1 and the second gate electrode GE2. The second gate electrode GE2 is in contact with the relay electrode R1 in the contact hole CH2. With this configuration, the second gate electrode GE2 is electrically connected to the scanning line GL1 as in the case of the first gate electrode GE1. In other words, the first gate electrode GE1 and the second gate electrode GE2 are at the same potential as that of the scanning line GL1.

In the vicinity of the contact hole CH1 formed in the insulating film interposed between the scanning line GL1 and the relay electrode R1 a contact hole CH1′ is formed, which plays a similar role to that of the contact hole CH1. Similarly, in the vicinity of the contact hole CH2 formed in the insulating film interposed between the relay electrode R1 and the second gate electrode GE2, a contact hole CH2′ is formed, which play a similar role to that of the contact hole CH2. These contact holes CH1′ and CH2′ are formed to ensure the yield of the display panel PNL. Although a detailed description is omitted, contact holes CH3′ to CH9′, which are formed in the vicinities of contact holes CH3 to CH9, respectively, to be described later, as well are contact holes formed to ensure the yield of the display panel PNL.

Both the source electrode SO and the drain electrode DE are formed in a linear form. The source electrode SO and the drain electrode DE are each formed to extend along the second direction Y and are aligned along the first direction X at intervals. The source electrode SO is in contact with one end side of each of the semiconductor members OS. The drain electrode DE is in contact with the other end side of each of the semiconductor members OS.

One end portion of the drain electrode DE overlaps the pixel electrode PE (see FIG. 2) corresponding to the pixel PX1. A contact hole CH3 is formed in the insulating film interposed between the drain electrode DE and the pixel electrode PE. The drain electrode DE is in contact with the pixel electrode PE in the contact hole CH3. With this configuration, the switching element SW is electrically connected to the pixel electrode PE.

The signal lines SL1 and SL3 extend along the second direction Y white interchanging their left and right positions with respect to each other (see FIG. 2). The signal lines SL2 and SL4 extend along the second direction Y while interchanging their left and right positions with respect to each other (see FIGS. 2 to 4).

The signal line SL1 extends along the second direction Y and intersects the scanning line GL1. The signal line SL1 overlaps the first gate electrode GE1 (scanning line GL1), the semiconductor members OS and the second gate electrode GE2.

The signal line SL3 does not intersect the scanning line GL1, but is divided into two parts, a first portion SL31 and a second portion SL32, from the scanning line GL1 as a boundary. The first portion SL31 and the second portion SL32 of the signal line SL3 each extend along the second direction Y and are aligned along the second direction Y so as to be spaced apart from each other. The first portion SL31 of the signal line SL3 is aligned with each of the signal line SL1 and the first portion SL21 of the signal line SL2 along the first direction X so as to be spaced apart therefrom. The second portion SL32 of signal line SL3 is aligned with each of the signal line SL1 and the second portion SL42 of the signal line SL4 along the first direction X so as to be spaced apart therefrom.

The first portion SL31 and the second portion SL32 of the signal line SL3 are electrically connected to each other by a relay electrode R2 disposed on the signal line SL3. In the insulating film interposed between the signal line SL3 and the relay electrode R2, contact holes CH4 and CH5 are formed. The first portion SL31 of the signal line SL3 is in contact with the relay electrode R2 in the contact hole CH4, and the second portion SL32 of the signal line SL3 is in contact with the relay electrode R2 in the contact hole CH5.

The signal line SL2 does not intersect the scanning line GL1, but is divided into two parts, a first portion SL21 and a second portion SL22 from the scanning line GL1 as a boundary. The first portion SL21 of the signal line SL2 extends along the second direction Y. The second portion SL22 of the signal line SL2 extends substantially along the second direction Y, while bending so as to interchange the left and right positions with the signal line SL4. The first portion SL21 of the signal line SL2 is aligned with each of the first portion SL31 of the signal line SL3 and the first portion SL41 of the signal line SL4 along the first direction X so as to be spaced apart therefrom. The second portion SL22 of the signal line SL2 is aligned with the second portion SL42 of the signal line SL4 along the first direction X so as to be spaced apart therefrom.

The first portion SL21 and the second portion SL22 of the signal line SL2 are electrically connected to each other by a relay electrode R3 disposed on the signal line SL2. In the insulating film interposed between the signal line SL2 and the relay electrode R3, contact holes CH6 and CH7 are formed. The first portion SL21 of the signal line SL2 is in contact with the relay electrode R3 in the contact hole CH6, and the second portion SL22 of the signal line SL2 is in contact with the relay electrode R3 in the contact hole CH7.

The signal line SL4 is divided into two parts, a first portion SL41 and a second portion SL42, while intersecting the scanning line GL1. The first portion SL41 and the second portion SL42 of the signal line SL4 each extend along the second direction Y. The first portion SL41 of the signal line SL4 is aligned with the first portion SL21 of the signal line SL2 along the first direction X so as to be spaced apart therefrom. The second portion SL42 of the signal line SL4 is aligned with each of the second portion SL32 of the signal line SL3 and the second portion SL22 of the signal line SL2 along the first direction X so as to be spaced apart therefrom.

The first portion SL41 and the second portion SL42 of the signal line SL4 are electrically connected to each other by a relay electrode R4 disposed under the signal line SL4. In the insulating film interposed between the signal line SL4 and the relay electrode R4, contact holes CH8 and CH9 are formed. The first portion SL41 of the signal line SL4 is in contact with the relay electrode R4 in the contact hole CH8, and the second portion SL42 of the signal line SL4 is in contact with the relay electrode R4 in the contact hole CH9.

FIG. 5 is a plan view showing in detail elements (mainly the first gate electrode GE1 and the second gate electrode GE2) that constitutes the switching element SW of the first embodiment. As shown in FIG. 5, the first gate electrode GE1 and the second gate electrode GE2 includes notches NT1 and NT2, respectively.

More specifically, the first gate electrode GE1 has the notch NT1 formed in a region between semiconductor members OS aligned along the second direction Y, which overlaps the source electrode SO integrated with the signal line SL1. With this configuration, the area where the source electrode SO and the first gate electrode GE1 oppose each other can be reduced, and therefore the parasitic capacitance formed between the source electrode SO and the first gate electrode GE1 can be reduced (that is, the load capacitance applied on the signal line SL1 including the source electrode SO can be reduced).

Similarly, the second gate electrode GE2 has the notch NT2 formed in a region between semiconductor members OS aligned along the second direction Y, which overlaps the source electrode SO integrated with the signal line SL1. With this configuration, the area where the source electrode SO and the second gate electrode GE2 oppose each other can be reduced, and therefore the parasitic capacitance formed between the source electrode SO and the second gate electrode GE2 can be reduced (in other words, the load capacitance applied on the signal line SL1 including the source electrode SO can be reduced).

Note that as shown in FIG. 5, both notches NT1 and NT2 should preferably be formed to cut, not a drain electrode DE side, but a source electrode SO side.

Further, in FIG. 5, the shapes of the first gate electrode GE1 and the second gate electrode GE2 included in the switching element SW that includes the source electrodes SO integrated with the signal line SL1 are shown. Note that the illustration may be similarly applied to the shapes of the first gate electrode GE1 and the second gate electrode GE2 included in the switching element SW that includes a source electrode SO integrated with any one of the other signal lines SL2 to SL4. In other words, the first gate electrode GE1 and the second gate electrode GE2 have notches NT1 and NT2, respectively, formed in the region between semiconductor members OS aligned along the second direction Y, which overlaps the source electrode SO integrated with any one of the signal lines SL1 to SL4.

With the notches NT1 and NT2 formed as described above, a plurality of apertures AP are formed in the regions between semiconductor members OS aligned along the second direction Y, as shown in FIG. 5.

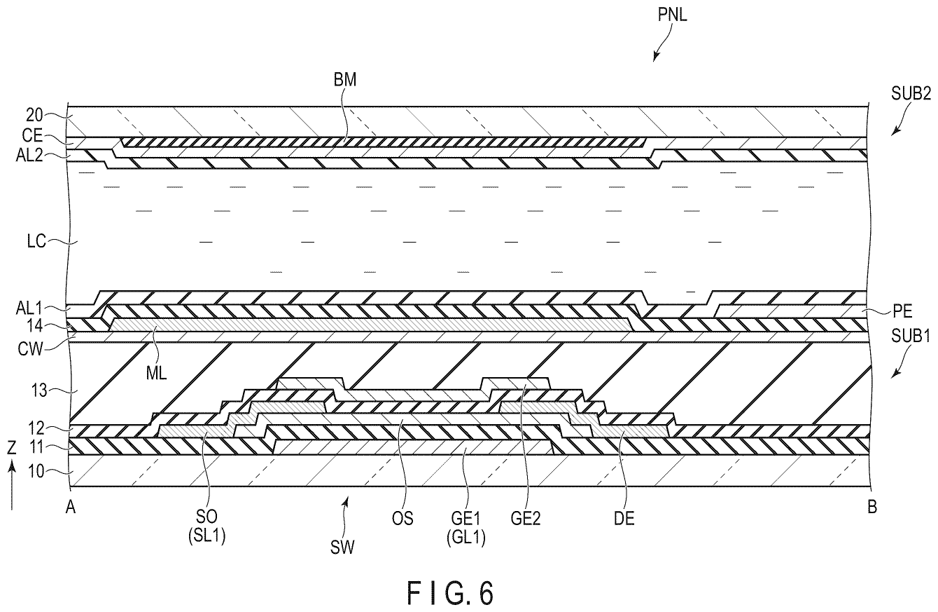

FIG. 6 is a cross-sectional view line A-B in FIG. 5. As described above, the display panel PNL comprises a first substrate SUB1, a second substrate SUB2, and a liquid crystal layer LC disposed between the first substrate SUB1 and the second substrate SUB2.

The first substrate SUB1 includes a first transparent substrate 10, insulating films 11 to 14, a switching element SW, a capacitive line CW, a metal line ML, a pixel electrode PE, and an alignment film AL1.

The first gate electrode GE1, which is integrated with the scanning line GL1, is disposed on the transparent substrate 1 10. The first gate electrode GE1 is formed, for example, from a metal material. The insulating film 11 covers the first transparent substrate 10 and the first gate electrode GE1. The insulating film 11 may as well be referred to as a gate insulating film. A semiconductor member OS is disposed on the insulating film 11 and located directly above the first gate electrode GE1. The source electrode SO, which is integrated with the signal line SL1, and the drain electrode DE, are disposed on the insulating film 11 and are each brought into contact with the semiconductor members OS. The source electrode SO and the drain electrode DE are formed of the same metal material. The insulating film 12 covers the insulating film 11, the source electrode SO, and the drain electrode DE. Further, between the source electrode SO and the drain electrode DE, the insulating film 12 is brought into contact with the semiconductor members OS.

The second gate electrode GE2 is disposed on the insulating film 12 and is located directly above the first gate electrode GE1 and the semiconductor member OS. The second gate electrode GE2 is formed, for example, from a metal material. The insulating film 13 covers the insulating film 12 and the second gate electrode GE2.

The capacitive line CW is disposed on the insulating film 13. The metal line ML is disposed on the capacitive line CW so as to be brought into contact with the capacitive line CW. The insulating film 14 covers the capacitive line CW and the metal line ML. The pixel electrode PE is disposed on the insulating film 14. The alignment film ALI covers the pixel electrode PE and the insulating film 14.

The insulating films 11, 12, and 14 are each a transparent inorganic insulating film such as of silicon oxide, silicon nitride, silicon oxynitride or the like. The insulating film 13 is, for example, a transparent organic insulating film such as acrylic resin, and the capacitive line CW and the pixel electrode PE are each a transparent electrode formed of a transparent conductive material such as indium tin oxide (ITO) or indium zinc oxide (IZO).

The second substrate SUB2 comprises a second transparent substrate 20, a light-shielding layer BM, a common electrode CE, and an alignment film AL2.

The light-shielding layer BM is disposed to oppose the switching element SW via the liquid crystal layer LC. The common electrode CE is disposed to oppose the pixel electrode PE via the liquid crystal layer LC. The alignment film AL2 covers the common electrode CE.

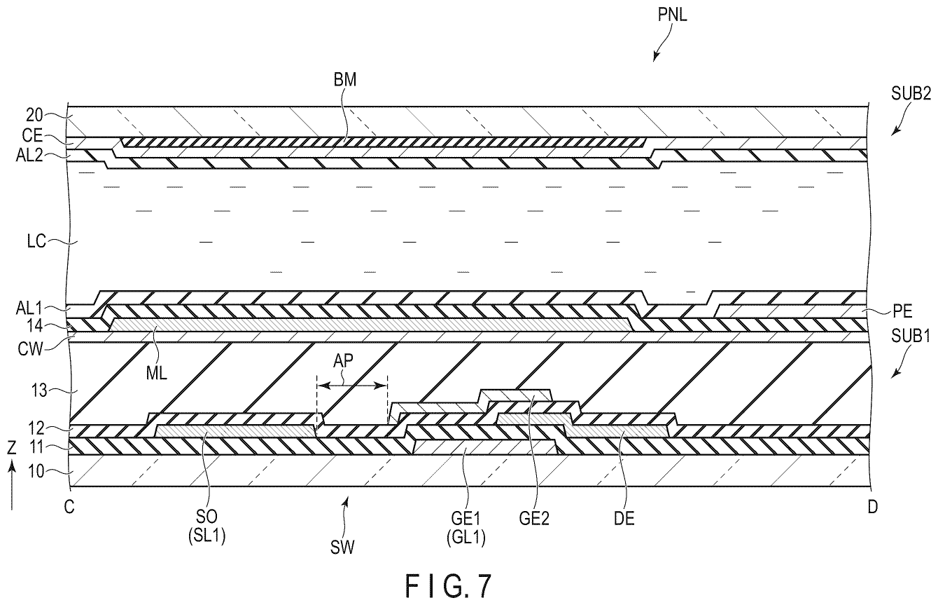

FIG. 7 is a cross-sectional view line C-D in FIG. 5. In other words, FIG. 7 is a schematic cross-sectional view of the display panel PNL in a region between adjacent semiconductor members OS aligned along the second direction Y. As shown in FIG. 7, in the region between semiconductor members OS aligned along the second direction Y, the first gate electrode GE1 and the source electrode SO integrated with the signal line SL1 do not oppose each other. Similarly, as shown in FIG. 7, in the region between the semiconductor members OS aligned along the second direction Y, the second gate electrode GE2 and the source electrode SO integrated with the signal line SL1 do not oppose each other. Note that, as shown in FIG. 7, the region from one end of the source electrode so integrated with the signal line SL1 to one end of the second gate electrode GE2 is the region corresponding to an aperture AP shown in FIG. 5.

As described above, the display panel PNL of the first embodiment comprises, as a switching element SW connected to each pixel PX, a switching element SW including a first gate electrode GE1 having a notch NT1 formed in a region overlapping a source electrode SO, and a second gate electrode GE2 having a notch NT2 formed in a region overlapping a source electrode SO. According to this configuration, the parasitic capacitance formed between the source electrode SO and the first gate electrode GE1 and the parasitic capacitance formed between the source electrode SO and the second gate electrode GE2 can both be reduced. Therefore, for example, as compared to a configuration in which both the first gate electrode GE1 and the second gate electrode GE2 do not have respective notches, the load capacitance applied on the signal line SL integrated with the source electrode SO can be significantly reduced.

### Second Embodiment

Next, the second embodiment will be described. The configuration of the second embodiment is different from that of the first embodiment described above in that the first gate electrode GE1 that constitutes the switching element SW does not have a notch NT1. Note that in the following descriptions, mainly the points that differ from those of the first embodiment will be described, and the description of the points similar to the first embodiment will be omitted.

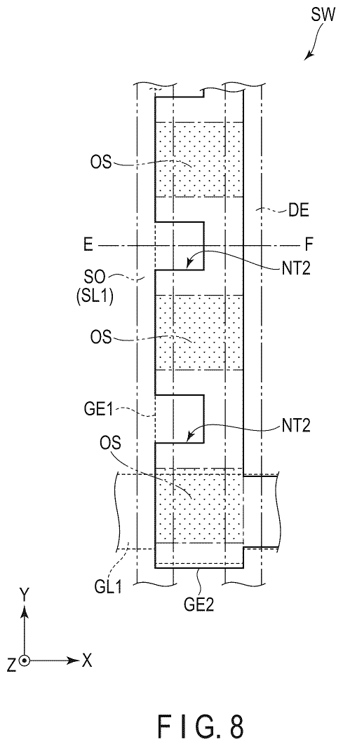

FIG. 8 is a plan view showing in detail elements that constitute the switching element SW of the second embodiment. As shown in FIG. 8, the first gate electrode GE1 is formed into a rectangular shape elongated along the second direction Y and has no notch. With this configuration, the first gate electrode GE1 overlaps the source electrode SO (signal line SL1) in a region between semiconductor members OS aligned along the second direction Y. Further, the first gate electrode GE1 does not have a notch, and therefore the apertures AP shown in FIG. 5 are not formed in the regions between the semiconductor members OS aligned along the second direction Y.

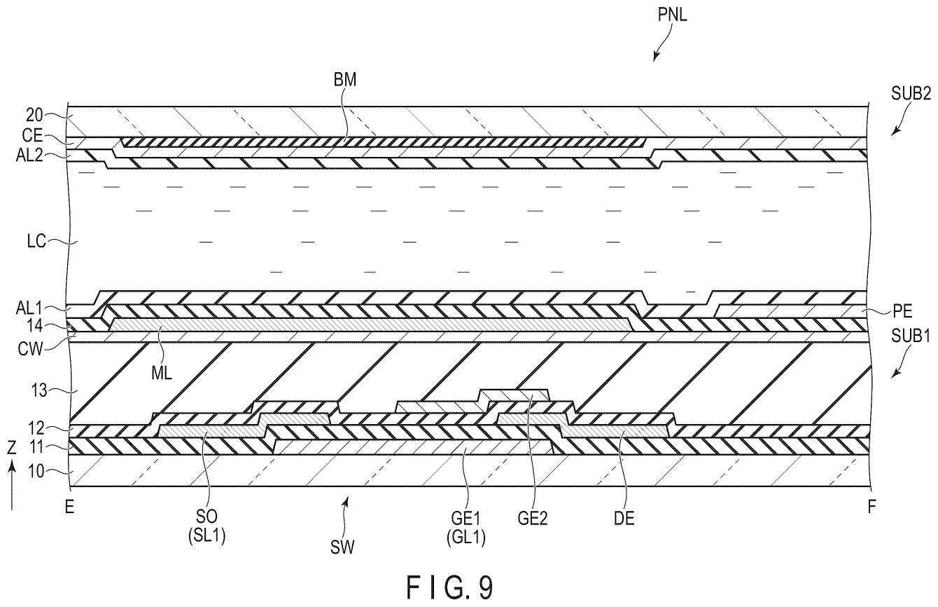

FIG. 9 is a cross-sectional view schematically showing the display panel PNL taken along line E-F in FIG. 8. As shown in FIG. 9, in a region between semiconductor members OS aligned along the second direction Y, the first gate electrode GE1 is disposed to oppose the source electrode SO, which is integrated with the signal line SL1. On the other hand, as shown in FIG. 9, in the region between the semiconductor members OS aligned along the second direction Y, the second gate electrode GE2 does not oppose the source electrode SO integrated with the signal line SL1.

According to this configuration, although the parasitic capacitance formed between the source electrode SO and the first gate electrode GE1 cannot be reduced, the parasitic capacitance formed between the source electrode SO and the second gate electrode GE2 can be reduced. Thus, for example, as compared to a configuration in which both the first gate electrode GE1 and the second gate electrode GE2 do not have notches, the load capacitance applied on the signal line SL integrated with the source electrode SO can be reduced.

Further, in the configuration of the second embodiment, the apertures AP shown in FIG. 5 are not formed as described above, and therefore, the following advantageous effects can be obtained.

That is, since the switching element SW includes elements formed from metal materials, such as the source electrode SO and the drain electrode DE, for example, when light hits the switching element SW, light reflection may occur, resulting in a degradation of the display quality. Therefore, it is desirable that the region overlapping the switching element SW in plan view should be light-shielded.

Here, incidentally, the display panel PNL is a so-called transparent display, and the images displayed in the display area DA can be seen from both the first substrate SUB1 side and the second substrate SUB2 side. Therefore, in the display panel PNL, it is desirable that the region overlapping the switching element SW in plan view should be light-shielded on both the first substrate SUB1 side and the second substrate SUB2 side.

In the configuration of the first embodiment described above, a light-shielding layer BM is arranged in the region on the second substrate SUB2 side, that overlaps the switching element SW in plan view (see FIGS. 6 and 7). With this configuration, light from the second substrate SUB2 side (second transparent substrate 20) toward the switching element SW can be blocked by the light-shielding layer BM, and the deterioration of display quality described above can be suppressed. On the other hand, in the configuration of the first embodiment described above, an aperture AP is formed in the region on the first substrate SUB1 side, which overlaps the switching element SW in plan view, and therefore light toward the switching element SW from the first substrate SUB1 side (first transparent substrate 10) cannot be blocked (see FIG. 7). With this configuration, light entering from the first substrate SUB1 side and transmitted through the aperture AP may be reflected by the switching element SW, resulting in degradation of the display quality.

By contrast, in the configuration of the second embodiment, since the first gate electrode GE1 does not have a notch, the first gate electrode GE1 is placed in the region on the first substrate SUB1 side, which overlaps the switching element SW in plan view, as shown in FIG. 9. With this configuration, the first gate electrode GE1 can function as a light-shielding layer that shades light toward the switching element SW from the first substrate SUB1 side, the region overlapping the switching element SW in plan view can be light-shaded on both the first substrate SUB1 side and the second substrate SUB2 side. Therefore, as compared to the configuration of the first embodiment, the degradation of the display quality can be suppressed.

### Third Embodiment

Further, the third embodiment will be described. The configuration of the third embodiment is different from that of the first embodiment described above in that the second gate electrode GE2 that constitutes the switching element SW does not have the notch NT2. In the following descriptions, mainly the points that differ from those of the first embodiment will be described, and the description of the points similar to those of the first embodiment will be omitted.

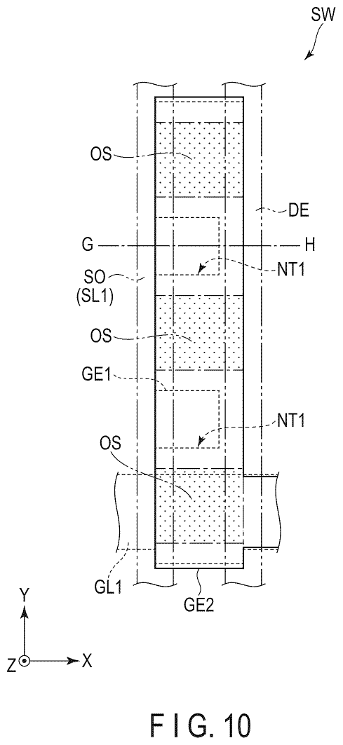

FIG. 10 is a plan view showing in detail elements that constitute the switching element SW of the third embodiment. As shown in FIG. 10, the second gate electrode GE2 does not have a notch and overlaps the source electrode SO (signal line SL1) in a region between semiconductor members OS aligned along the second direction Y.

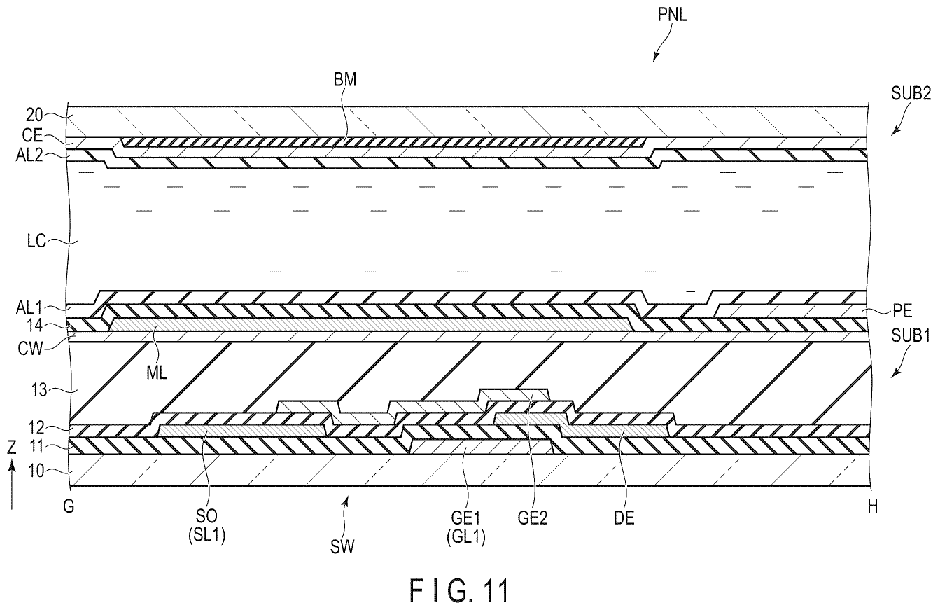

FIG. 11 is a cross-sectional view schematically showing the display panel PNL taken along line G-H in FIG. 10. As shown in FIG. 11, in the region between semiconductor members OS aligned along the second direction Y, the second gate electrode GE2 is disposed to oppose the source electrode SO, which is integrated with the signal line SL1. On the other hand, as shown in FIG. 11, in the region between the semiconductor members OS aligned along the second direction Y, the first gate electrode GE1 does not oppose the source electrode SO, which is integrated with the signal line SL1.

According to this configuration, although the parasitic capacitance formed between the source electrode SO and the second gate electrode GE2 cannot be reduced, the parasitic capacitance formed between the source electrode SO and the first gate electrode GE1 can be reduced. Thus, for example, as compared to a configuration in which both the first gate electrode GE1 and the second gate electrode GE2 do not have respective notches, the load capacitance applied on the signal line SL integrated with the source electrode SO can be reduced.

According to at least one of the embodiments provided above, it is possible to provide an array substrate and a display device, which can reduce the load capacitance applied to the signal line SL integrated with the source electrode SO and thus to suppress a decrease in reliability.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An array substrate comprising:
a transparent substrate;
a linear source electrode disposed on the transparent substrate;
a linear drain electrode disposed on a same layer as that of the source electrode;
at least two semiconductor members connected in parallel between the source electrode and the drain electrode; and
a gate electrode overlapping the source electrode, the drain electrode and the at least two semiconductor members,
wherein
the gate electrode comprises a notch formed in a region between the at least two semiconductor members.

2. The array substrate of claim 1, wherein
the gate electrode includes a first gate electrode disposed below the source electrode and the drain electrode and a second gate electrode disposed above the source electrode and the drain electrode, and
the first gate electrode and the second gate electrode each comprise a notch formed in a region between the at least two semiconductor members.

3. The array substrate of claim 1, wherein
the gate electrode includes a first gate electrode disposed below the source electrode and the drain electrode and a second gate electrode disposed above the source electrode and the drain electrode, and
only the second gate electrode comprises a notch formed in a region between the at least two semiconductor members.

4. The array substrate of claim 1, wherein
the gate electrode includes a first gate electrode disposed below the source electrode and the drain electrode and a second gate electrode disposed above the source electrode and the drain electrode, and
only the first gate electrode comprises a notch formed in a region between the at least two semiconductor members.

5. The array substrate of claim 1, wherein
the notch is formed to cut a source electrode side of the gate electrode.

6. The array substrate of claim 1, wherein
the source electrode and the drain electrode are aligned along a first direction at an interval, and each extend along a second direction that intersects the first direction, and
the at least two semiconductor members are aligned along the second direction at an interval between the source electrode and the drain electrode.

7. A display device comprising:
a transparent substrate;
a linear source electrode disposed on the transparent substrate;
a linear drain electrode disposed on a same layer as that of the source electrode;
at least two semiconductor members connected in parallel between the source electrode and the drain electrode; and
a gate electrode overlapping the source electrode, the drain electrode and the at least two semiconductor members,
wherein
the gate electrode comprises a notch formed in a region between the at least two semiconductor members.

8. The display device of claim 7, wherein
the gate electrode includes a first gate electrode disposed below the source electrode and the drain electrode and a second gate electrode disposed above the source electrode and the drain electrode, and
the first gate electrode and the second gate electrode each comprise a notch formed in a region between the at least two semiconductor members.

9. The display device of claim 7, wherein
the gate electrode includes a first gate electrode disposed below the source electrode and the drain electrode and a second gate electrode disposed above the source electrode and the drain electrode, and
only the second gate electrode comprises a notch formed in a region between the at least two semiconductor members.

10. The display device of claim 7, wherein
the gate electrode includes a first gate electrode disposed below the source electrode and the drain electrode and a second gate electrode disposed above the source electrode and the drain electrode, and
only the first gate electrode comprises a notch formed in a region between the at least two semiconductor members.

11. The display device of claim 7, wherein
the notch is formed to cut a source electrode side of the gate electrode.

12. The display device of claim 7, wherein
the source electrode and the drain electrode are aligned along a first direction at an interval, and each extend along a second direction that intersects the first direction, and
the at least two semiconductor members are aligned along the second direction at an interval between the source electrode and the drain electrode.
